(19) United States
(12) Patent Application Publication
(10) Pub. No.: US 2026/0304604 A1
(43) Pub. Date: Oct. 1, 2026

(54) FLEXIBLE PRINTED CIRCUIT

(71) Applicants: MEKTEC CORPORATION, Tokyo (JP); ISUZU MOTORS LIMITED, Yokohama-shi (JP)

(72) Inventors: Nobuo Matsuba, Fujisawa-shi (JP); Shogo Takeda, Fujisawa-shi (JP); Yusuke Hosono, Fujisawa-shi (JP); Atsushi Omori, Tokyo (JP); Michihiro Unno, Tokyo (JP); Takatoshi Abe, Tokyo (JP)

(73) Assignees: MEKTEC CORPORATION, Tokyo (JP); ISUZU MOTORS LIMITED, Yokohama-shi (JP)

(21) Appl. No.: 19/629,439

(22) Filed: Mar. 26, 2026

(30) Foreign Application Priority Data
Mar. 27, 2025 (JP) 2025-053969

(51) Int. Cl. H05K 1/02

(52) U.S. Cl. CPC H05K 1/0277; H05K 2201/09027

(57) ABSTRACT

The present invention provides a flexible printed circuit having a structure capable of favorably suppressing breakage of a circuit body. A flexible printed circuit, includes: a flexible circuit body having a substrate, wiring formed on the substrate, and an insulating coating covering the wiring; and a reinforcing plate laminated on the circuit body, in which the circuit body includes a first portion and a second portion extending from the first portion with a smaller width than the first portion, the reinforcing plate is laminated on at least the first portion among the first portion and the second portion, and when viewed in a thickness direction of the circuit body, the reinforcing plate is disposed at a position offset toward inward side of the circuit body with respect to a boundary point P1 between the first portion and the second portion in an outline of the circuit body.

### CROSS-REFERENCE TO RELATED APPLICATIONS

This application claims the benefits of Japanese Patent Application No. 2025-53969 filed on Mar. 27, 2025 in the Japanese Patent Office, the disclosures of which are herein incorporated in its entirety by reference.

### BACKGROUND OF THE INVENTION

The present invention relates to flexible printed circuit (FPC).

Japanese Laid-open patent publication NO. 2013-38154 describes a flexible printed circuit including a circuit body having a band shape and a connector provided at one end portion of the circuit body. On the circuit body of the flexible printed circuit of Japanese Laid-open patent publication NO. 2013-38154, a reinforcing plate having the same width dimension as the circuit body is laminated on a portion near the connector.

### Citation List

### Patent Literature

Patent Literature 1: Japanese Laid-open patent publication NO. 2013-38154

### SUMMARY OF THE INVENTION

However, according to the study of the inventors, there is still room for improvement in the technique of Japanese Laid-open patent publication NO. 2013-38154 from the viewpoint of favorably suppressing the breakage of the circuit body.

The present invention has been made in view of the above problems, and provides a flexible printed circuit having a structure capable of favorably suppressing the breakage of the circuit body.

According to the present invention, there is provided a flexible printed circuit, including:
a flexible circuit body having a substrate, wiring formed on the substrate, and an insulating coating covering the wiring; and
a reinforcing plate laminated on the circuit body, in which
the circuit body includes a first portion and a second portion extending from the first portion with a smaller width than the first portion,
the reinforcing plate is laminated on at least the first portion among the first portion and the second portion, and
when viewed in a thickness direction of the circuit body, the reinforcing plate is disposed at a position offset toward inward side of the circuit body with respect to a boundary point between the first portion and the second portion in an outline of the circuit body.

According to the present invention, it is possible to satisfactorily suppress the breakage of the circuit body.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a perspective view of a flexible printed circuit according to an embodiment;

FIG. 2 is a perspective view of the flexible printed circuit according to the embodiment viewed from an opposite side from FIG. 1;

FIG. 3 is an exploded perspective view of the flexible printed circuit according to the embodiment;

FIG. 4 is a view of one end portion of the flexible printed circuit according to the embodiment viewed from a back surface side;

FIG. 5 is a view illustrating a middle portion in a longitudinal direction of the flexible printed circuit according to the embodiment;

FIG. 6 is an enlarged view of a portion A of FIG. 5;

FIG. 7 is a view illustrating a middle portion in the longitudinal direction of the flexible printed circuit according to the embodiment, the middle portion being different from the portion illustrated in FIG. 5;

FIG. 8 is a partially enlarged view of other end portion of the flexible printed circuit according to the embodiment;

FIG. 9 is a view in which a metal plate of a configuration illustrated in FIG. 8 is not illustrated;

FIG. 10 is a schematic cross-sectional view illustrating a layer configuration of the flexible printed circuit according to the embodiment;

FIG. 11 is a perspective view of a flexible printed circuit according to a modification; and

FIG. 12 is a perspective view of the flexible printed circuit according to the modification viewed from an opposite side from FIG. 11.

### DESCRIPTION OF EMBODIMENT

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, an embodiment and a modification of the present invention will be described with reference to the drawings. Note that, in all the drawings, the similar components are denoted by the same reference numerals, and the description thereof will not be repeated.

### Embodiment

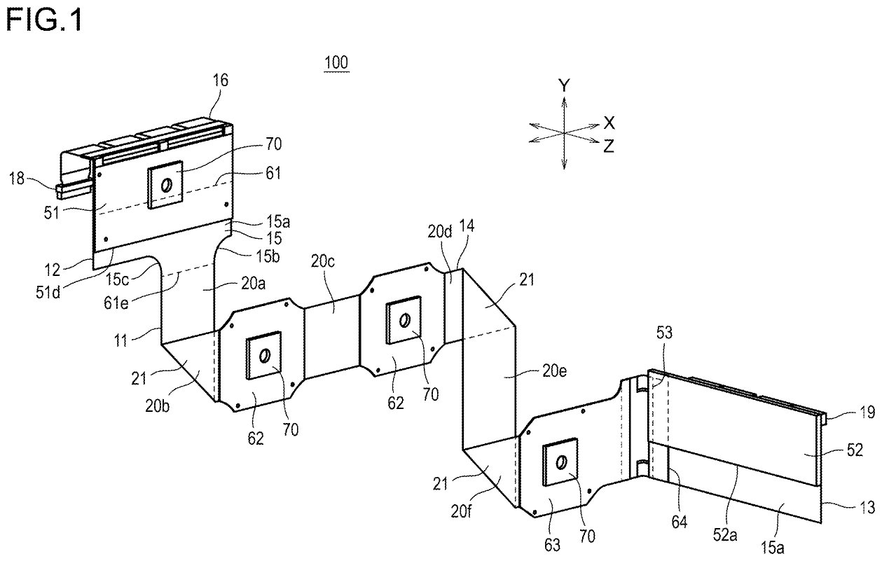

First, an embodiment will be described with reference to FIGS. 1 to 10.

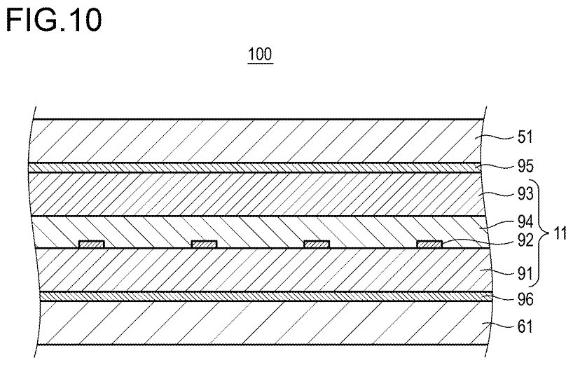

As illustrated in FIG. 10, the flexible printed circuit 100 according to the present embodiment includes a flexible circuit body 11 having a substrate 91, wiring 92 formed on the substrate 91, and an insulating coating 93 covering the wiring 92, and a reinforcing plate (first metal plate 51, second reinforcing film 62, and the like illustrated in FIG. 1 and the like) laminated on the circuit body 11.

The circuit body 11 includes a first portion (described later) and a second portion (described later) extending from the first portion with a smaller width than the first portion.

The reinforcing plate is laminated on at least the first portion among the first portion and the second portion.

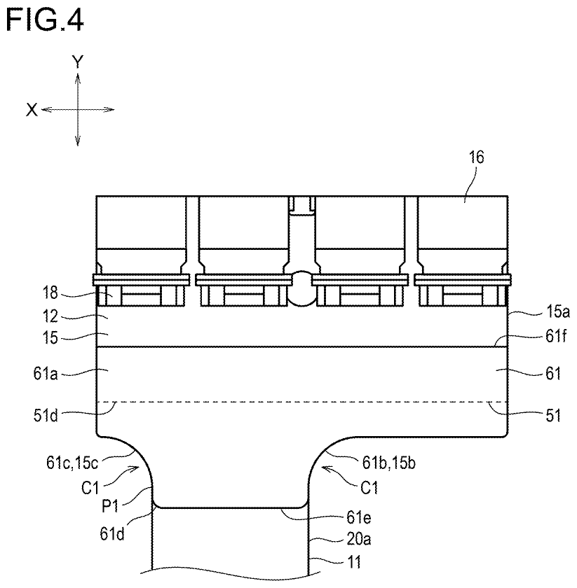

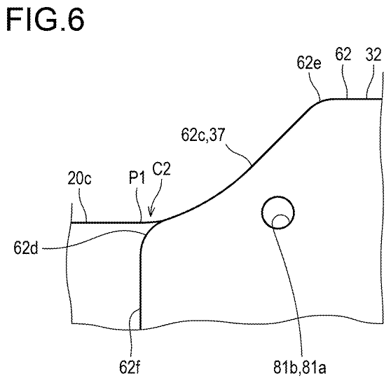

When viewed in a thickness direction of the circuit body 11, the reinforcing plate is disposed at a position offset toward inward side of the circuit body 11 with respect to a boundary point P1 (FIGS. 4 and 6) between the first portion and the second portion in the outline of the circuit body 11.

According to the present embodiment, when viewed in the thickness direction of the circuit body 11, when the reinforcing plate is disposed at a position offset toward inward side of the circuit body 11 with respect to a boundary point P1 between the first portion and the second portion in the outline of the circuit body 11, it is possible to favorably suppress the breakage of the circuit body 11, the breakage of the circuit body 11 starting from a portion of overlapping with an end portion of the reinforcing plate. Therefore, it is possible to suppress breakage of the circuit body 11 at the time of attachment work of the flexible printed circuit 100, breakage of the circuit body 11 when the flexible printed circuit 100 is subjected to vibration, and the like.

Hereinafter, the present embodiment will be described in more detail.

In the following description, the positional relationship of each component may be described using an X direction, a Y direction, and a Z direction illustrated in FIGS. 1 to 3 and the like. The X direction, the Y direction, and the Z direction are orthogonal to each other. The X direction, the Y direction, and the Z direction are illustrated as bidirectional arrows. Of the bidirectional arrows, directions with letters (X, Y, Z) may be referred to as +X direction, +Y direction, and +Z direction, respectively, and directions without letters may be referred to as −X direction, −Y direction, and −Z direction, respectively.

Hereinafter, for convenience, the +X direction may be referred to as right, the −X direction may be referred to as left, the +Y direction may be referred to as up, the −Y direction may be referred to as down, the +Z direction may be referred to as front, and the −Z direction may be referred to as rear.

FIG. 10 is a layer configuration in a case where the flexible printed circuit 100 is single-sided FPC. In this case, the circuit body 11 has a substrate 91, wiring 92 formed on the substrate 91, and an insulating coating 93 covering the wiring 92. The substrate 91 and the insulating coating 93 are adhering to each other via an adhesive layer 94.

FIG. 10 illustrates a schematic cross section of a region of the flexible printed circuit 100 where a first metal plate 51 and a first reinforcing film 61 are laminated on the circuit body 11. The first metal plate 51 is bonded to the circuit body 11 (on the insulating coating 93) via the adhesive layer 95. The first reinforcing film 61 is bonded to the circuit body 11 (on the substrate 91 (under the substrate 91 in the positional relationship illustrated in FIG. 10)) via the adhesive layer 96.

FIG. 10 illustrates an example in which the first metal plate 51 is bonded to one surface of the circuit body 11 and the first reinforcing film 61 is bonded to the other surface of the circuit body 11, but the first reinforcing film 61 may be interposed between the first metal plate 51 and the circuit body 11.

The positional relationship between the first metal plate 51 and the first reinforcing film 61 may be reversed from the positional relationship illustrated in FIG. 10. That is, the first metal plate 51 may be bonded to the circuit body 11 via the adhesive layer 96 (on the substrate 91 (under the substrate 91 in the positional relationship shown in FIG. 10)), and the first reinforcing film 61 may be bonded to the circuit body 11 via the adhesive layer 95 (on the insulating coating 93).

The flexible printed circuit 100 according to the present embodiment is, for example, a long FPC cable having a band shape. As an example, such an FPC cable is mounted on a vehicle, and can be used by being connected to a vehicle battery or a peripheral device of the vehicle battery.

As illustrated in FIGS. 1 to 3, in the case of the present embodiment, the circuit body 11 is formed in a band shape, and connectors 18 and 19 connected to external devices are respectively provided at both ends (one end portion 12 and other end portion 13) of the circuit body 11, respectively.

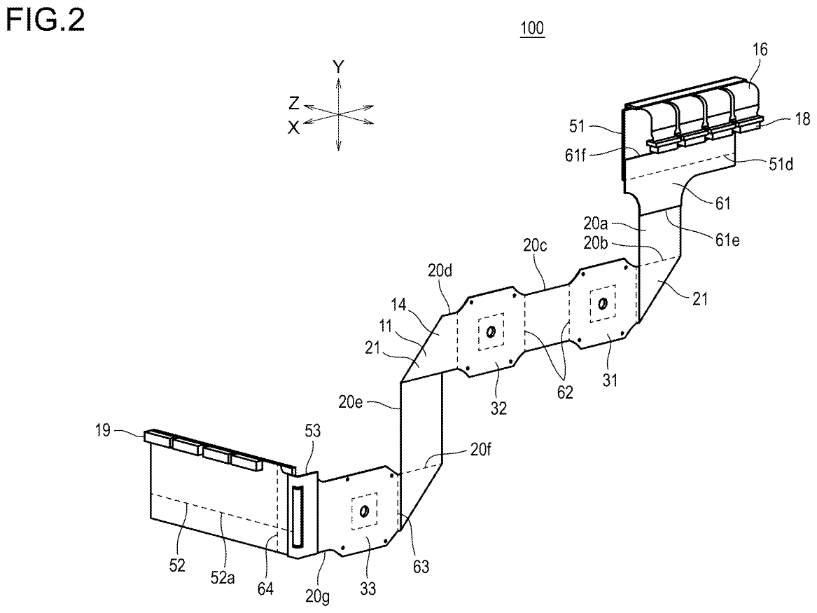

FIGS. 1 and 2 illustrate an example of the shape of the flexible printed circuit 100 in a state where the flexible printed circuit 100 is attached to an attachment object.

The following describes the shape of the flexible printed circuit 100 in a state where the flexible printed circuit 100 is attached to an attachment object.

In the case of the present embodiment, the circuit body 11 has one end portion 12, other end portion 13, and a middle portion 14 which is a portion between the one end portion 12 and the other end portion 13.

In the present embodiment, the middle portion 14 has, in order from the one end portion 12 side, a first narrow-width portion 20a, a second narrow-width portion 20b, a first expanded portion 31, a third narrow-width portion 20c, a second expanded portion 32, a fourth narrow-width portion 20d, a fifth narrow-width portion 20e, a sixth narrow-width portion 20f, a third expanded portion 33, a seventh narrow-width portion 20g, a fourth expanded portion 34, and a connecting portion 22, and the other end portion 13 is adjacent to the connecting portion 22.

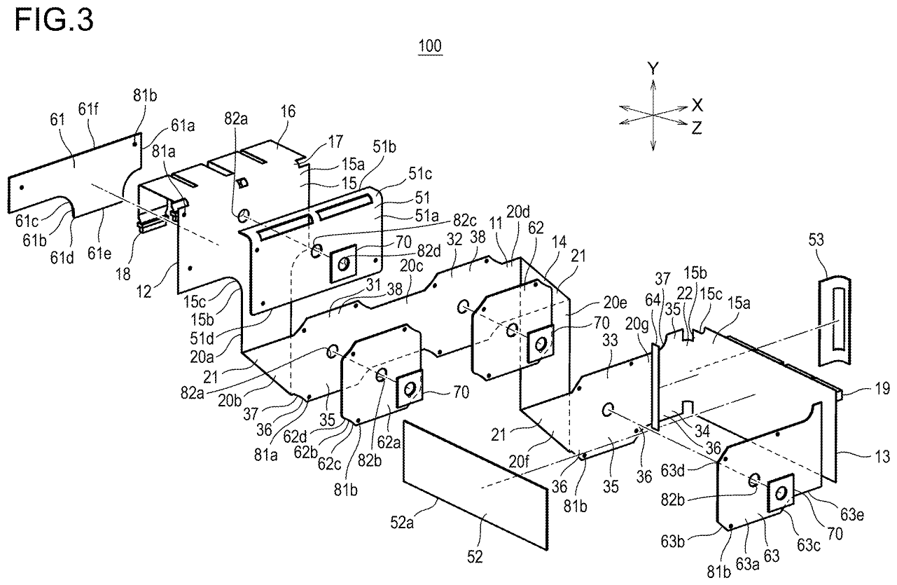

As illustrated in FIG. 3, the one end portion 12 has a wide-width portion 15, a branch portion 16 that branches into a plurality of portions with their respective distal ends and is bent in the-Z direction with respect to the wide-width portion 15, and a connecting portion 17 that connects the branch portion 16 and the wide-width portion 15. A connector 18 is provided at each of the distal ends of the branch portion 16.

In the wide-width portion 15, front and back principal surfaces of the wide-width portion 15 face the Z direction.

Similarly, front and back principal surfaces of each of the first narrow-width portion 20a, the second narrow-width portion 20b, the first expanded portion 31, the third narrow-width portion 20c, the second expanded portion 32, the fourth narrow-width portion 20d, the fifth narrow-width portion 20e, the sixth narrow-width portion 20f, the third expanded portion 33, the seventh narrow-width portion 20g, and the fourth expanded portion 34 face the Z direction.

However, the first narrow-width portion 20a and the second narrow-width portion 20b are folded back in opposite directions, and a boundary portion between the first narrow-width portion 20a and the second narrow-width portion 20b is, for example, a folded portion 21 having a right-angled isosceles triangle shape, and portions of the first narrow-width portion 20a and the second narrow-width portion 20b overlap each other at the folded portion 21.

Similarly, the fourth narrow-width portion 20d and the fifth narrow-width portion 20e are folded back in opposite directions, and a boundary portion between the fourth narrow-width portion 20d and the fifth narrow-width portion 20e is, for example, a folded portion 21 having a right-angled isosceles triangle shape, and portions of the fourth narrow-width portion 20d and the fifth narrow-width portion 20e overlap each other at the folded portion 21.

Similarly, the fifth narrow-width portion 20e and the sixth narrow-width portion 20f are folded back in opposite directions, and a boundary portion between the fifth narrow-width portion 20e and the sixth narrow-width portion 20f is, for example, a folded portion 21 having a right-angled isosceles triangle shape, and portions of the fifth narrow-width portion 20e and the sixth narrow-width portion 20f overlap each other at the folded portion 21.

The first narrow-width portion 20a continuous with the wide-width portion 15 extends downward from the wide-width portion 15.

The above-described folded portion 21 is formed at a boundary portion between the first narrow-width portion 20a and the second narrow-width portion 20b continuous with the first narrow-width portion 20a. Therefore, the second narrow-width portion 20b, the first expanded portion 31 continuous with the second narrow-width portion 20b, the third narrow-width portion 20c continuous with the first expanded portion 31, the second expanded portion 32 continuous with the third narrow-width portion 20c, and the fourth narrow-width portion 20d continuous with the second expanded portion 32 extend rightward from the lower end portion (folded portion 21) of the first narrow-width portion 20a.

The above-described folded portion 21 is formed at a boundary portion between the fourth narrow-width portion 20d and the fifth narrow-width portion 20e continuous with the fourth narrow-width portion 20d. Therefore, the fifth narrow-width portion 20e extends downward from the right side portion of the fourth narrow-width portion 20d.

The above-described folded portion 21 is formed at a boundary portion between the fifth narrow-width portion 20e and the sixth narrow-width portion 20f continuous with the fifth narrow-width portion 20e. Therefore, the sixth narrow-width portion 20f, the third expanded portion 33 continuous with the sixth narrow-width portion 20f, the seventh narrow-width portion 20g continuous with the third expanded portion 33, and the fourth expanded portion 34 continuous with the seventh narrow-width portion 20g extend rightward from the lower end portion of the fifth narrow-width portion 20e.

The other end portion 13 is bent in the +Z direction with respect to the fourth expanded portion 34, and the front and back principal surfaces of the other end portion 13 face the X direction.

The connecting portion 22 connects the other end portion 13 and the fourth expanded portion 34, and the other end portion 13 is bent with respect to the fourth expanded portion 34 by bending the circuit body 11 at the connecting portion 22.

The wide-width portion 15 has a larger dimension (width dimension) in the X direction than the first narrow-width portion 20a continuous with the wide-width portion 15.

The wide-width portion 15 has a constant width portion 15a having a constant dimension in the X direction, and a boundary portion 15b between the wide-width portion 15 and the first narrow-width portion 20a.

The dimension (width dimension) of the boundary portion 15b in the X direction gradually decreases toward the first narrow-width portion 20a side (that is, downward).

A recessed portion 15c having a shape indented arcuately is formed in the outline of the boundary portion 15b of the wide-width portion 15.

The recessed portions 15c are respectively formed at both ends in the width direction (X direction) of the boundary portion 15b of the wide-width portion 15.

The first narrow-width portion 20a has a constant dimension (width dimension) in the X direction except for a portion serving as the folded portion 21.

The second narrow-width portion 20b has a constant dimension (width dimension) in the Y direction except for a portion serving as the folded portion 21.

The first expanded portion 31 has a larger dimension (width dimension) in the Y direction than the second narrow-width portion 20b and the third narrow-width portion 20c located respectively on both sides of the first expanded portion 31.

The first expanded portion 31 has a constant width portion 35 having a constant dimension in the Y direction, and a boundary portion 36 formed in succession to the left and right of the constant width portion 35.

The constant width portion 35 is formed in, for example, a substantially square shape.

The dimension (width dimension) of a left boundary portion 36 of the first expanded portion 31 in the Y direction gradually decreases toward the second narrow-width portion 20b side (left). An upper edge of the left boundary portion 36 is declined toward the left (for example, declined at an angle of about 45 degrees). A lower edge of the left boundary portion 36 is inclined upward toward the left (for example, inclined upward at an angle of about 45 degrees). The vertical dimension of a left edge of the left boundary portion 36 is set to be the same dimension as the vertical dimension of the second narrow-width portion 20b.

The dimension (width dimension) of a right boundary portion 36 of the first expanded portion 31 in the Y direction gradually decreases toward the third narrow-width portion 20c side (right). An upper edge of the right boundary portion 36 is declined toward the right (for example, declined at an angle of about 45 degrees). The lower edge of the right boundary portion 36 is inclined upward toward the right (for example, inclined upward at an angle of about 45 degrees). The vertical dimension of a right edge of the right boundary portion 36 is set to be the same dimension as the vertical dimension of the third narrow-width portion 20c.

A recessed portion 37 having a shape indented arcuately is formed in the outline of each boundary portion 36.

The recessed portions 37 are respectively formed at both ends in the width direction (Y direction) of each boundary portion 36.

The recessed portion 37 of the upper edge of the left boundary portion 36 has a shape recessed in the lower right direction.

The recessed portion 37 of the lower edge of the left boundary portion 36 has a shape recessed in the upper right direction.

The recessed portion 37 of the upper edge of the right boundary portion 36 has a shape recessed in the lower left direction.

The recessed portion 37 of the lower edge of the right boundary portion 36 has a shape recessed in the upper left direction.

Therefore, the first expanded portion 31 has a substantially octagonal shape, but four sides of the octagonal shape are recessed portions 37 each indented arcuately inward.

The third narrow-width portion 20c has a constant dimension (width dimension) in the Y direction.

The second expanded portion 32 has a larger dimension (width dimension) in the Y direction than the third narrow-width portion 20c and the fourth narrow-width portion 20d respectively located on both sides of the second expanded portion 32.

That is, the second expanded portion 32 has a constant width portion 35 having a constant dimension in the Y direction, and a boundary portion 36 formed in succession to the left and right of the constant width portion 35.

The constant width portion 35 of the second expanded portion 32 is also formed in, for example, a substantially square shape.

The dimension (width dimension) of the left boundary portion 36 of the second expanded portion 32 in the Y direction gradually decreases toward the third narrow-width portion 20c side (left). An upper edge of the left boundary portion 36 is declined toward the left (for example, declined at an angle of about 45 degrees). A lower edge of the left boundary portion 36 is inclined upward toward the left (for example, inclined upward at an angle of about 45 degrees). The vertical dimension of a left edge of the left boundary portion 36 is set to be the same dimension as the vertical dimension of the third narrow-width portion 20c.

The dimension (width dimension) of the right boundary portion 36 of the second expanded portion 32 in the Y direction gradually decreases toward the fourth narrow-width portion 20d side (right). An upper edge of the right boundary portion 36 is declined toward the right (for example, declined at an angle of about 45 degrees). The lower edge of the right boundary portion 36 is inclined upward toward the right (for example, inclined upward at an angle of about 45 degrees). The vertical dimension of a right edge of the right boundary portion 36 is set to be the same dimension as the vertical dimension of the fourth narrow-width portion 20d.

Also in the second expanded portion 32, a recessed portion 37 having a shape indented arcuately is formed in the outline of each boundary portion 36, and the recessed portions 37 are respectively formed at both ends in the width direction (Y direction) of each boundary portion 36.

The recessed portion 37 of the upper edge of the left boundary portion 36 has a shape recessed in the lower right direction.

The recessed portion 37 of the lower edge of the left boundary portion 36 has a shape recessed in the upper right direction.

The recessed portion 37 of the upper edge of the right boundary portion 36 has a shape recessed in the lower left direction.

The recessed portion 37 of the lower edge of the right boundary portion 36 has a shape recessed in the upper left direction.

Therefore, the second expanded portion 32 has a substantially octagonal shape, but four sides of the octagonal shape are recessed portions 37 each indented arcuately inward.

The shape and dimension of the second expanded portion 32 are, for example, the same as those of the first expanded portion 31.

The fourth narrow-width portion 20d has a constant dimension (width dimension) in the Y direction except for a portion serving as the folded portion 21.

The fifth narrow-width portion 20e has a constant dimension (width dimension) in the X direction except for a portion serving as the folded portion 21.

The sixth narrow-width portion 20f has a constant dimension (width dimension) in the Y direction except for a portion serving as the folded portion 21.

For example, the width dimensions of the first narrow-width portion 20a, the second narrow-width portion 20b, the third narrow-width portion 20c, the fourth narrow-width portion 20d, the fifth narrow-width portion 20e, and the sixth narrow-width portion 20f are equal to each other.

The first expanded portion 31 has protruding portions 38 which are portions projecting up and down from the second narrow-width portion 20b and the third narrow-width portion 20c that are adjacent to the left and right of the first expanded portion 31.

The protruding portion 38 on the upper side of the first expanded portion 31 is a portion projecting up from the upper edges of the second narrow-width portion 20b and the third narrow-width portion 20c.

The protruding portion 38 on the lower side of the first expanded portion 31 is a portion projecting downward from the lower edges of the second narrow-width portion 20b and the third narrow-width portion 20c.

Similarly, the second expanded portion 32 has protruding portions 38 which are portions projecting up and down from the third narrow-width portion 20c and the fourth narrow-width portion 20d adjacent to the left and right of the second expanded portion 32.

The protruding portion 38 on the upper side of the second expanded portion 32 is a portion projecting up from the upper edges of the third narrow-width portion 20c and the fourth narrow-width portion 20d.

The protruding portion 38 on the lower side of the second expanded portion 32 is a portion projecting downward from the lower edges of the third narrow-width portion 20c and the fourth narrow-width portion 20d.

The third expanded portion 33 has a larger dimension (width dimension) in the Y direction than the sixth narrow-width portion 20f and the seventh narrow-width portion 20g located on both sides of the third expanded portion 33.

The third expanded portion 33 has a constant width portion 35 having a constant dimension in the Y direction, and a boundary portion 36 formed in succession to the left and right of the constant width portion 35.

The dimension (width dimension) of the left boundary portion 36 of the third expanded portion 33 in the Y direction gradually decreases toward the sixth narrow-width portion 20f side (left). An upper edge of the left boundary portion 36 of the third expanded portion 33 is declined toward the left (for example, declined at an angle of about 45 degrees). A lower edge of the left boundary portion 36 of the third expanded portion 33 is inclined upward toward the left (for example, inclined upward at an angle of 45 degrees). The vertical dimension of a left edge of the left boundary portion 36 of the third expanded portion 33 is set to be the same dimension as the vertical dimension of the sixth narrow-width portion 20f.

The dimension (width dimension) of the right boundary portion 36 of the third expanded portion 33 in the Y direction gradually decreases toward the seventh narrow-width portion 20g side (right). Note that the upper edge of the right boundary portion 36 of the third expanded portion 33 is located on the extension of the upper edge of the constant width portion 35 of the third expanded portion 33. On the other hand, the lower edge of the right boundary portion 36 of the third expanded portion 33 is inclined upward toward the right (for example, declined at an angle of about 45 degrees). The vertical dimension of a right edge of the right boundary portion 36 of the third expanded portion 33 is set to be the same dimension as the vertical dimension of the seventh narrow-width portion 20g.

The recessed portion 37 is formed on one side (lower side) in the width direction of the boundary portion 36 of the right of the third expanded portion 33. The recessed portion 37 has a shape recessed in the upper left direction.

The seventh narrow-width portion 20g has a constant dimension (width dimension) in the Y direction.

The fourth expanded portion 34 has a larger dimension (width dimension) in the Y direction than the seventh narrow-width portion 20g located on the left of the fourth expanded portion 34.

The fourth expanded portion 34 has a constant width portion 35 having a constant dimension in the Y direction, and a boundary portion 36 formed in succession to the left of the constant width portion 35.

The dimension (width dimension) of the boundary portion 36 of the fourth expanded portion 34 in the Y direction gradually decreases toward the seventh narrow-width portion 20g side (left). An upper edge of the boundary portion 36 of the fourth expanded portion 34 is declined toward the left (for example, declined at an angle of about 45 degrees). The vertical dimension of a left edge of the boundary portion 36 of the fourth expanded portion 34 is set to be the same dimension as the vertical dimension of the seventh narrow-width portion 20g. The recessed portion 37 is formed on one side (upper side) in the width direction of the boundary portion 36 of the fourth expanded portion 34. The recessed portion 37 has a shape recessed in the lower right direction.

The other end portion 13 has a constant width portion 15a having a constant dimension in the Y direction, and a boundary portion 15b formed in succession to the rear (−Z direction) of the constant width portion 15a.

A dimension (width dimension) of the boundary portion 15b of the other end portion 13 in the Y direction gradually decreases toward the rear. An upper edge of the boundary portion 15b of the other end portion 13 is declined to the rear (for example, declined at an angle of about 45 degrees). A recessed portion 15c is formed in the upper edge of the boundary portion 15b of the other end portion 13. The recessed portion 15c has a shape recessed downward on the front side.

A connector 19 is provided to the other end portion 13.

The connecting portion 22 connects the fourth expanded portion 34 and the other end portion 13.

The width dimension (vertical dimension) of the connecting portion 22 is smaller than, for example, the width dimension (vertical dimension) of the boundary portion 15b of the other end portion 13 and the width dimension (vertical dimension) of the fourth expanded portion 34.

A first metal plate 51 is attached to one surface of the one end portion 12.

The first metal plate 51 has, for example, a main portion 51a which is a flat plate portion having a rectangular shape, a sub portion 51b, and a bent portion 51c which is a portion connecting the sub portion 51b and the main portion 51a.

The main portion 51a is a portion of the first metal plate 51 attached to the constant width portion 15a of the wide-width portion 15. The lateral width dimension of the main portion 51a is equal to the lateral width dimension of the constant width portion 15a. When viewed in the thickness direction of the circuit body 11, the left edge of the main portion 51a and the left edge of the constant width portion 15a overlap (coincide) with each other, and the right edge of the main portion 51a and the right edge of the constant width portion 15a overlap (coincide) with each other.

A lower edge of the main portion 51a, that is, an edge portion 51d of the first metal plate 51 on the first narrow-width portion 20a side extends, for example, in a lateral direction.

The edge portion 51d is located above the lower edge of the constant width portion 15a.

In the first metal plate 51, a sub portion 51b is attached to a portion near the connecting portion 17 in the branch portion 16.

The first metal plate 51 is bent by 90 degrees at a bent portion 51c between the main portion 51a and the sub portion 51b. Consequently, the main portion 51a and the sub portion 51b are orthogonal to each other.

Slits (two slits, for example) extending in the lateral direction are formed in the bent portion 51c, and thus the first metal plate 51 is easily bent at the bent portion 51c.

The first metal plate 51 has a flat plate shape as a whole before being attached to the circuit body 11. After the first metal plate 51 is attached to the circuit body 11, the first metal plate 51 is bent along the slit at the bent portion 51c, whereby the circuit body 11 is bent together with the first metal plate 51, and the circuit body 11 can be maintained in the shape after being bent.

In the constant width portion 15a, the first reinforcing film 61 is attached to a surface opposite to the surface to which the main portion 51a is attached.

The first reinforcing film 61 has a constant width portion 61a having a constant lateral width dimension and a rectangular shape, and a width changing portion 61b formed continuously below the constant width portion 61a.

The lateral width dimension of the width changing portion 61b gradually decreases toward the first narrow-width portion 20a side (that is, downward).

The edge portion 61f on the upper side of the first reinforcing film 61 (the upper edge of the constant width portion 61a) extends, for example, in the lateral direction.

The edge portion 61e on the lower side of the first reinforcing film 61 (the lower edge of the width changing portion 61b) extends, for example, in the lateral direction.

Therefore, the edge portion 61f and the edge portion 61e extend in parallel to each other, for example.

For example, the edge portion 61f is located below an upper end of the constant width portion 15a.

The lateral width dimension of the constant width portion 61a is equal to the lateral width dimension of the constant width portion 15a.

When viewed in the thickness direction of the circuit body 11, the left edge of the constant width portion 61a and the left edge of the constant width portion 15a overlap (coincide) with each other, the right edge of the constant width portion 61a and the right edge of the constant width portion 15a overlap (coincide) with each other, and the lower edge of the constant width portion 61a and the lower edge of the constant width portion 15a overlap (coincide) with each other.

A recessed portion 61c having a shape indented arcuately is formed in the outline of the width changing portion 61b.

The recessed portions 61c are respectively formed at both ends in the width direction (X direction) of the width changing portion 61b.

The width changing portion 61b is attached, for example, over a region from the boundary portion 15b to the upper end portion of the first narrow-width portion 20a.

The shape of the width changing portion 61b is formed in a shape corresponding to the region from the boundary portion 15b to the upper end portion of the first narrow-width portion 20a, and when viewed in the thickness direction of the circuit body 11, the recessed portion 61c of the width changing portion 61b and the recessed portion 15c of the boundary portion 15b overlap (coincide) with each other.

An arc-shaped portion 61d is formed at each of the corner portions of the left and right ends at the lower end of the width changing portion 61b.

The arc-shaped portion 61d is formed in an arc shape protruding outward from the first reinforcing film 61.

An arc-shaped portion 61d on the left side at the lower end of the width changing portion 61b is formed in a shape arcuately protruding in the lower left direction.

An arc-shaped portion 61d on the right side at the lower end of the width changing portion 61b is formed in a shape arcuately protruding in the lower right direction.

On the other hand, as described above, the recessed portion 61c is formed in an arc shape indented arcuately, that is, in an arc shape arcuately protruding toward inward side of the first reinforcing film 61.

The radius of curvature of the recessed portion 61c is larger than the radius of curvature of the arc-shaped portion 61d.

The radius of curvature of the recessed portion 61c is, for example, equal to or larger than twice the radius of curvature of the arc-shaped portion 61d. As an example, the radius of curvature of the recessed portion 61c can be set to about 15 mm, and the radius of curvature of the arc-shaped portion 61d can be set to about 3 mm.

As illustrated in FIG. 4, the outline of the arc-shaped portion 61d is offset inward with respect to the outline of the circuit body 11.

A second reinforcing film 62 is attached to each of one surface of the first expanded portion 31 and one surface of the second expanded portion 32.

The second reinforcing film 62 is formed in substantially the same shape as the first expanded portion 31 and the second expanded portion 32. That is, the second reinforcing film 62 has a substantially octagonal shape.

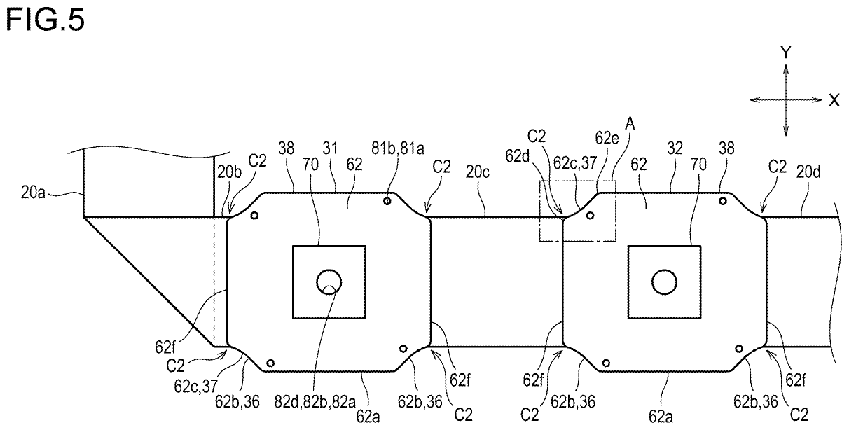

More specifically, as illustrated in FIG. 5, the second reinforcing film 62 is formed in the same shape as the first expanded portion 31 and the second expanded portion 32 except for the shape of an arc-shaped portion 62d described later.

When viewed in the thickness direction of the circuit body 11, the outline of the second reinforcing film 62 attached to the first expanded portion 31 coincides with the outline of the first expanded portion 31 except for the outline of the arc-shaped portion 62d.

Similarly, when viewed in the thickness direction of the circuit body 11, the outline of the second reinforcing film 62 attached to the second expanded portion 32 coincides with the outline of the second expanded portion 32 except for the outline of the arc-shaped portion 62d.

The outline of the arc-shaped portion 62d is offset inward with respect to the outline of the circuit body 11.

The second reinforcing film 62 has a constant width portion 62a having a constant vertical width dimension, a width changing portion 62b formed in succession to the left side of the constant width portion 62a, and a width changing portion 62b formed in succession to the right side of the constant width portion 62a.

The constant width portion 62a is formed in, for example, a substantially square shape.

The width changing portion 62b on the left side of the second reinforcing film 62 has a vertical width dimension gradually decreasing toward the left.

An upper edge of the width changing portion 62b on the left side is declined toward the left (for example, declined at an angle of about 45 degrees). The lower edge of the width changing portion 62b on the left side is inclined upward toward the left (for example, inclined upward at an angle of about 45 degrees).

The width changing portion 62b on the right side of the second reinforcing film 62 has a vertical width dimension gradually decreasing toward the right.

An upper edge of the width changing portion 62b on the right side is declined toward the right (for example, declined at an angle of about 45 degrees). The lower edge of the width changing portion 62b on the right side is inclined upward toward the right (for example, inclined upward at an angle of about 45 degrees).

A recessed portion 62c having a shape indented arcuately is formed in the outline of each of the width changing portions 62b.

The recessed portions 62c are respectively formed at both ends in the width direction (Y direction) of the width changing portion 62b.

The recessed portion 62c of the upper edge of the width changing portion 62b on the left side has a shape recessed in the lower right direction.

The recessed portion 62c of the lower edge of the width changing portion 62b on the left side has a shape recessed in the upper right direction.

The recessed portion 62c of the upper edge of the width changing portion 62b on the right side has a shape recessed in the lower left direction.

The recessed portion 62c of the lower edge of the width changing portion 62b on the right side has a shape recessed in the upper left direction.

A corner portion at an upper end of the left edge of the width changing portion 62b on the left side is an arc-shaped portion 62d protruding outward of the second reinforcing film 62. The arc-shaped portion 62d protrudes toward the upper left direction.

A corner portion of the lower end at the left edge of the width changing portion 62b on the left side is an arc-shaped portion 62d protruding outward of the second reinforcing film 62. The arc-shaped portion 62d protrudes toward the lower left direction.

A corner portion of the upper end at the right edge of the width changing portion 62b on the right side is an arc-shaped portion 62d protruding outward of the second reinforcing film 62. The arc-shaped portion 62d protrudes toward the upper right direction.

A corner portion of the lower end at the right edge of the width changing portion 62b on the right side is an arc-shaped portion 62d protruding outward of the second reinforcing film 62. The arc-shaped portion 62d protrudes toward the lower right direction.

Each of the arc-shaped portions 62d is offset inward with respect to the outline of the circuit body 11. Therefore, the vertical dimension of the left edge of the second reinforcing film 62 (the vertical dimension of the left edge of the width changing portion 62b on the left side) is smaller than the vertical dimension of the left edge of each of the first expanded portion 31 and the second expanded portion 32 (the vertical dimension of the left edge of the left boundary portion 36 of each of the first expanded portion 31 and the second expanded portion 32). Similarly, the vertical dimension of the right edge of the second reinforcing film 62 (the vertical dimension of the right edge of the width changing portion 62b on the right side) is smaller than the vertical dimension of the right edge of each of the first expanded portion 31 and the second expanded portion 32 (the vertical dimension of the right edge of the right boundary portion 36 of each of the first expanded portion 31 and the second expanded portion 32).

An upper corner portion at a boundary position between the width changing portion 62b on the left side and the constant width portion 62a is an arc-shaped portion 62e protruding outward from the second reinforcing film 62. The arc-shaped portion 62e protrudes toward the upper left direction.

A lower corner portion at a boundary position between the width changing portion 62b on the left side and the constant width portion 62a is an arc-shaped portion 62e protruding outward from the second reinforcing film 62. The arc-shaped portion 62e protrudes toward the lower left direction.

An upper corner portion at a boundary position between the width changing portion 62b on the right side and the constant width portion 62a is an arc-shaped portion 62e protruding outward from the second reinforcing film 62. The arc-shaped portion 62e protrudes toward the upper right direction.

A lower corner portion at a boundary position between the width changing portion 62b on the right side and the constant width portion 62a is an arc-shaped portion 62e protruding outward from the second reinforcing film 62. The arc-shaped portion 62e protrudes toward the lower right direction.

The first expanded portion 31 and the second expanded portion 32 are also formed with arc-shaped portions having the same shape and the same position as those of the arc-shaped portions 62e, and when viewed in the thickness direction of the circuit body 11, the outlines of these arc-shaped portions and the outlines of the respective arc-shaped portions 62e coincide with each other.

The radius of curvature of the recessed portion 62c is larger than the radius of curvature of the arc-shaped portion 62d.

The radius of curvature of the recessed portion 62c is larger than the radius of curvature of the arc-shaped portion 62e.

The radius of curvature of the recessed portion 62c is, for example, equal to or larger than twice the radius of curvature of the arc-shaped portion 62d. As an example, the radius of curvature of the recessed portion 62c can be set to about 15 mm, and the radius of curvature of the arc-shaped portion 62d can be set to about 3 mm.

As an example, the radius of curvature of the arc-shaped portion 62e can be set to about the same as the radius of curvature of the arc-shaped portion 62d.

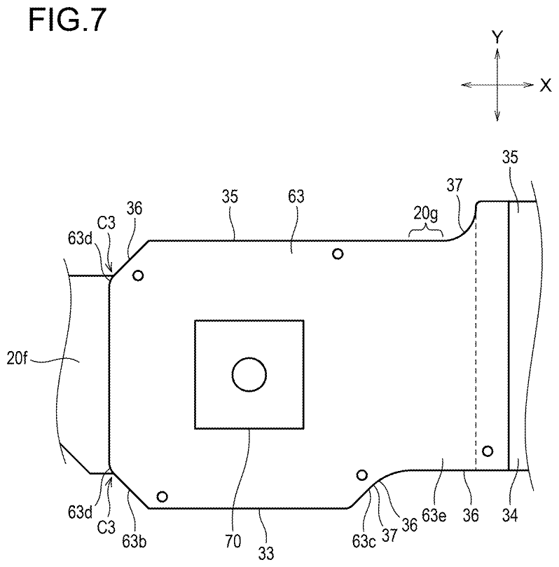

As illustrated in FIG. 7, the third reinforcing film 63 covers a portion from a right end portion of the sixth narrow-width portion 20f to a left end portion of the fourth expanded portion 34.

The third reinforcing film 63 is formed in substantially the same shape and size as the portion from the right end portion of the sixth narrow-width portion 20f to the left end portion of the fourth expanded portion 34, and when viewed in the thickness direction of the circuit body 11, the outline of the third reinforcing film 63 substantially coincides with the outline of the portion from the right end portion of the sixth narrow-width portion 20f to the left end portion of the fourth expanded portion 34.

However, the outline of an arc-shaped portion 63d of third reinforcing film 63 described later is offset inward with respect to the outline of circuit body 11.

The third reinforcing film 63 has a constant width portion 63a having a constant vertical width dimension, a width changing portion 63b formed in succession to the left side of the constant width portion 63a, and an extension portion 63e formed in succession to the right side of the constant width portion 63a.

The constant width portion 63a covers the constant width portion 35 of the third expanded portion 33.

The width changing portion 63b covers a portion from the left boundary portion 36 of the third expanded portion 33 to the right end portion of the sixth narrow-width portion 20f.

The extension portion 63e covers a portion from the right boundary portion 36 of the third expanded portion 33 to the left end portion of the fourth expanded portion 34.

Each of the upper and lower corner portions of the left edge portion of the width changing portion 63b is an arc-shaped portion 63d protruding outward of the third reinforcing film 63. The arc-shaped portion 63d at the upper corner portion of the left edge portion of the width changing portion 63b protrudes toward the upper left, and the arc-shaped portion 63d of the lower corner of the left edge portion of the width changing portion 63b protrudes toward the lower left.

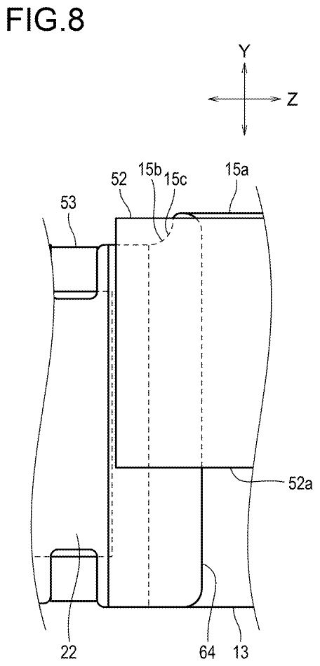

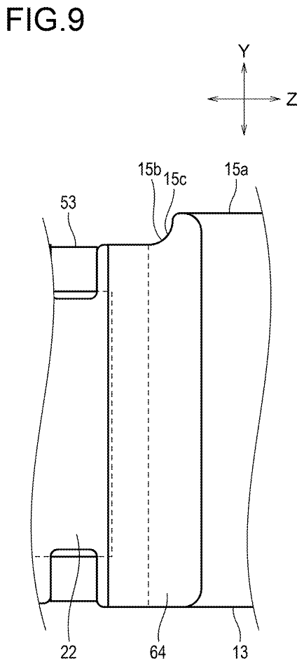

As illustrated in FIGS. 8 and 9, the fourth reinforcing film 64 is attached to one surface of a rear end portion of the other end portion 13. The fourth reinforcing film 64 covers, for example, a region from the upper end to the lower end in the rear end portion of the other end portion 13.

A second metal plate 52 is attached to, for example, an upper portion of one surface of the other end portion 13.

The second metal plate 52 is formed in, for example, a rectangular shape.

The front-rear dimension of the second metal plate 52 substantially coincides with the front-rear dimension of the other end portion 13.

The edge portion 52a (lower edge) of the second metal plate 52 is located above the lower edge of the other end portion 13.

Therefore, the upper portion of the fourth reinforcing film 64 is covered with the second metal plate 52, but the lower portion of the fourth reinforcing film 64 is exposed from the second metal plate 52.

A bent metal plate 53 is attached, for example, over the right end portion of the fourth expanded portion 34, the connecting portion 22, and the rear end portion of the other end portion 13.

The shape of the bent metal plate 53 in plan view (shape viewed in the −Y direction) is an L shape.

A slit extending in a vertical direction is formed in the bent metal plate 53, and the bent metal plate 53 is easily bent.

The bent metal plate 53 has a flat plate shape as a whole before being attached to the circuit body 11. After the bent metal plate 53 is attached to the circuit body 11, the bent metal plate 53 is bent along the slit, whereby the circuit body 11 is bent together with the bent metal plate 53, and the circuit body 11 can be maintained in the shape after being bent.

In order to attach each reinforcing film (first reinforcing film 61, second reinforcing film 62, and third reinforcing film 63) to the circuit body 11 in an aligned manner or to attach the first metal plate 51 to the circuit body 11 in an aligned manner, pin holes 81a, 81b, and 81c for alignment are formed in the circuit body 11, the reinforcing film, and the first metal plate 51, respectively.

Further, the flexible printed circuit 100 has a fastening hole for fastening the flexible printed circuit 100 to an object to be attached using a fastener (not illustrated).

The fastening holes 82a formed in the circuit body 11 and the fastening holes 82b formed in the respective reinforcing films (second reinforcing film 62, third reinforcing film 63) are disposed at positions corresponding to each other, and a common fastener can be inserted therethrough.

Similarly, the fastening holes 82a formed in the circuit body 11 and the fastening holes 82c formed in the first metal plate 51 are disposed at positions corresponding to each other, and a common fastener can be inserted therethrough.

Note that fastening portion reinforcing members 70 for reinforcing the flexible printed circuit 100 may be provided at the respective portions where the fastening holes are formed. In this case, the fastening portion reinforcing member 70 also has fastening holes 82d corresponding to the fastening holes of the circuit body 11 and the first metal plate 51, and fastening holes 82d corresponding to the fastening holes of the circuit body 11 and the reinforcing film.

Here, the structure of the first metal plate 51 and its periphery will be described in more detail.

As illustrated in FIG. 1, the first metal plate 51 is a reinforcing plate laminated on the circuit body 11.

The circuit body 11 includes a wide-width portion 15 (first portion) and a first narrow-width portion 20a (second portion) extending from the first portion with a smaller width than the first portion.

The first metal plate 51 is laminated on at least the wide-width portion 15 among the wide-width portion 15 (first portion) and the first narrow-width portion 20a (second portion). More specifically, the first metal plate 51 is laminated on only the wide-width portion 15 of the wide-width portion 15 and the first narrow-width portion 20a.

More specifically, the width dimension of the boundary portion 15b with the first narrow-width portion 20a (second portion) in the wide-width portion 15 (first portion) gradually decreases toward the first narrow-width portion 20a.

A recessed portion 15c having a shape indented arcuately is formed in the outline of the boundary portion 15b.

As illustrated in FIG. 4, when viewed in the thickness direction of the circuit body 11, the first metal plate 51 is disposed at a position offset toward inward side of the circuit body 11 with respect to a boundary point P1 between the wide-width portion 15 and the first narrow-width portion 20a in the outline of the circuit body 11. More specifically, the first metal plate 51 is disposed at a position offset inward (up in FIG. 4) of the wide-width portion 15 with respect to the boundary point P1.

That is, the flexible printed circuit 100 includes the first reinforcing plate (first metal plate 51) as the reinforcing plate, in which the entire first reinforcing plate is disposed at a position offset toward inward side of the first portion from the boundary point P1 between the first portion and the second portion when viewed in the thickness direction of the circuit body 11. The first reinforcing plate is a metal plate (first metal plate 51).

Consequently, it is possible to satisfactorily suppress the breakage of the circuit body 11 starting from the portion overlapping the end of the first metal plate 51 in the circuit body 11.

It is considered that the breakage of the circuit body 11 is likely to occur at a corner portion C1 from a portion having a wide width to a portion having a narrow width, but the stress on the corner portion C1 can be suppressed by the above-described configuration.

In addition, since the recessed portion 15c is formed in the corner portion C1, concentration of stress particularly at the boundary between the first narrow-width portion 20a having a narrow width and the width changing portion 61b can be suppressed, so that it is possible to further suppress breakage of the circuit body 11 at the corner portion C1.

The flexible printed circuit 100 includes a resin film (first reinforcing film 61) laminated on a surface of the circuit body 11 opposite to a surface on which the metal plate (first metal plate 51) is laminated, or interposed between the circuit body 11 and the metal plate. When viewed in the thickness direction of the circuit body 11, the resin film (first reinforcing film 61) is disposed across an edge portion 51d of the metal plate (first metal plate 51) on the second portion side.

This makes it possible to protect a region of the circuit body 11 overlapping the edge portion 51d of the first metal plate 51 by the first reinforcing film 61, so that breakage at the region can be suppressed.

In addition, since the arc-shaped portion 61d of the first reinforcing film 61 is offset toward inward side with respect to the outline of the circuit body 11, it is possible to suppress occurrence of breakage at a region corresponding to the edge portion 61e (edge portion having the arc-shaped portion 61d at the end portion) in the circuit body 11.

Next, the structure of the second reinforcing film 62 and its periphery will be described in more detail.

As illustrated in FIG. 6, the circuit body 11 includes a first portion (first expanded portion 31, second expanded portion 32) and a second portion (second narrow-width portion 20b, third narrow-width portion 20c, and fourth narrow-width portion 20d) extending from the first portion with a smaller width than the first portion.

The second reinforcing film 62 is laminated on at least the first portion among the first portion and the second portion. More specifically, the second reinforcing film 62 is laminated on at least the first portion among the first portion and the second portion.

When viewed in the thickness direction of the circuit body 11, the second reinforcing film 62 is disposed at a position offset toward inward side of the circuit body 11 with respect to a boundary point P1 (FIG. 6) between the first portion and the second portion in the outline of the circuit body 11.

Consequently, it is possible to satisfactorily suppress the breakage of the circuit body 11 starting from the portion overlapping the edge portion 62f (FIG. 6) on the second portion side of the second reinforcing film 62 in the circuit body 11.

It is considered that the breakage of the circuit body 11 is likely to occur at a corner portion C2 (FIGS. 5 and 6) from a portion having a wide width to a portion having a narrow width, but the stress on the corner portion C2 can be suppressed by the above-described configuration.

In addition, since the recessed portion 37 and the recessed portion 62c are formed in the corner portion C2, it is possible to further suppress concentration of stress at the corner portion C2, so as to suppress breakage of the circuit body 11 at the corner portion C2.

More specifically, the width dimension of the boundary portion (boundary portion 36) with the second portion in the first portion (first expanded portion 31, second expanded portion 32) gradually decreases toward the second portion side.

A recessed portion 37 having a shape indented arcuately is formed in the outline of the boundary portion 36.

A recessed portion 62c having a shape corresponding to the recessed portion 37 of the boundary portion 36 is also formed in the reinforcing plate (second reinforcing film 62), and when viewed in the thickness direction of the circuit body 11, the recessed portion 62c of the reinforcing plate and the recessed portion 62c of the boundary portion 36 overlap each other.

An arc-shaped portion 62d protruding outward from the reinforcing plate is formed at a corner of the reinforcing plate (second reinforcing film 62), and the arc-shaped portion 62d is disposed at a position offset toward inward side of the circuit body 11. Consequently, it is possible to satisfactorily suppress the breakage of the circuit body 11 starting from the portion overlapping the corner portion of the second reinforcing film 62 in the circuit body 11.

More specifically, the arc-shaped portion 62d is disposed at a position protruding toward the boundary point P1.

Further, the circuit body 11 is formed in a band shape, and the circuit body 11 has, as the first portion, an expanded portion (first expanded portion 31, second expanded portion 32) formed in a middle portion in the longitudinal direction of the circuit body, and includes, as the reinforcing plate, a resin film (second reinforcing film 62) laminated on the expanded portion. An arc-shaped portion 62d protruding outward from the resin film is formed at a corner portion of the resin film (second reinforcing film 62), and the arc-shaped portion 62d is disposed at a position offset toward inward side of the circuit body 11.

In addition, the width dimension of the boundary portion 36 with the second portion in the first portion (first expanded portion 31, second expanded portion 32) gradually decreases toward the second portion side, a recessed portion 37 having a shape indented arcuately is formed in the outline of the boundary portion 36, a recessed portion 62c corresponding to the recessed portion 37 of the boundary portion 36 is also formed in the reinforcing plate (second reinforcing film 62), and when viewed in the thickness direction of the circuit body 11, the recessed portion 62c of the reinforcing plate and the recessed portion 37 of the boundary portion 36 overlap each other.

Here, the arc-shaped portion 62d of the second reinforcing film 62 is continuous with the end of the recessed portion 62c of the second reinforcing film 62. That is, the arc-shaped portion 62d protruding outward is continuous with the recessed portion 62c that is an arc-shaped portion protruding inwardly. Consequently, the outline of the region from the recessed portion 62c to the arc-shaped portion 62d substantially does not contain a region having a linear shape. For this reason, it is possible to more suitably suppress the occurrence of breakage of the circuit body 11 along the outline of the second reinforcing film 62.

As described above, each of the first expanded portion 31 and the second expanded portion 32 has the protruding portion 38. Since the recessed portion 62c is formed in the protruding portion 38, the first expanded portion 31 and the second expanded portion 32 have a structure in which a steep change in rigidity at a root portion of the protruding portion 38 is suppressed. Consequently, it is possible to prevent the first expanded portion 31 and the second expanded portion 32 from being sharply bent at the root portion of the protruding portion 38.

When the flexible printed circuit 100 is attached, the circuit body 11 having a band shape may be twisted. In such a case, even if a bending force is applied to the protruding portion 38, it is possible to suppress sharp bending at the root portion of the protruding portion 38.

The corner portion of the second reinforcing film 62 is the arc-shaped portion 62e, and a portion corresponding to the arc-shaped portion 62e of the first expanded portion 31 and second expanded portion 32 has the same shape as that of the arc-shaped portion 62e. That is, the portion has a rounded shape and does not have a sharp shape.

Therefore, it is possible to suppress a corner portion of the protruding portion 38 (a portion where the arc-shaped portion 62e is formed) from being caught by something at the time of attachment work of the flexible printed circuit 100 or the like.

As illustrated in FIG. 7, since the arc-shaped portion 63d of the third reinforcing film 63 is also offset inward with respect to the outline of the circuit body 11, the breakage of the circuit body 11 at the corner portion C3 illustrated in FIG. 7 can be suppressed.

In addition, the stress on the circuit body 11 can also be suppressed by the recessed portion 63c formed in the extension portion 63e of the third reinforcing film 63.

Next, an example of a material of each part in the flexible printed circuit 100 will be described.

The substrate 91 and the insulating coating 93 are made of, for example, a resin material such as polyimide.

The wiring 92 is made of a metal material such as copper or aluminum.

The metal material constituting the metal plate (first metal plate 51 and second metal plate 52) is not particularly limited as long as sufficient rigidity can be secured, and for example, stainless steel, aluminum, or the like can be used.

The material constituting the resin film (first reinforcing film 61, second reinforcing film 62, third reinforcing film 63, and fourth reinforcing film 64) can be, for example, polyimide.

The thickness dimension of the resin film (first reinforcing film 61, second reinforcing film 62, third reinforcing film 63, and fourth reinforcing film 64) may be smaller than the thickness dimension of the circuit body 11 or may be larger than the thickness dimension of the circuit body 11. An adhesive (adhesive layer 96) is used for bonding the resin film, and the combined thickness dimension of the resin film and the adhesive layer 96 is preferably larger than the thickness dimension of the circuit body 11. By doing so, the reinforcing effect of the circuit body 11 by the resin film can be further enhanced.

### Modification

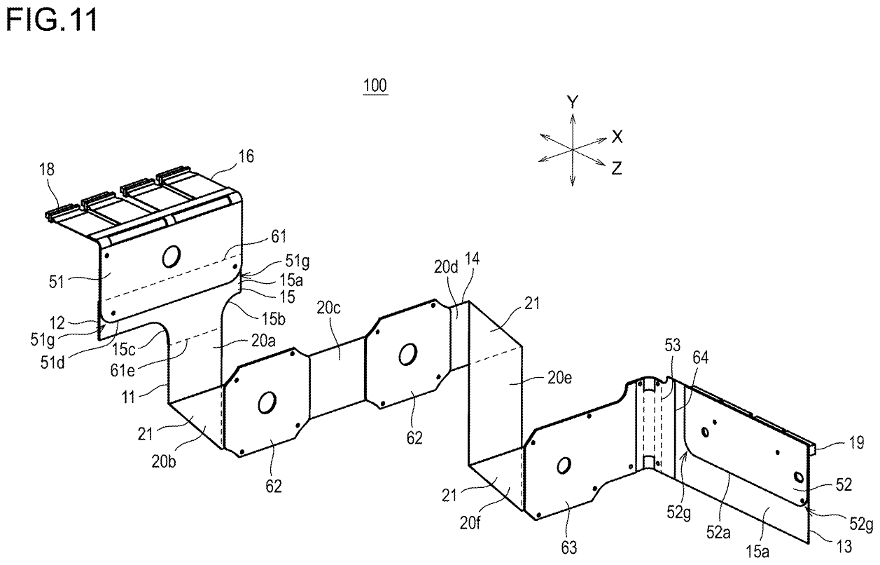

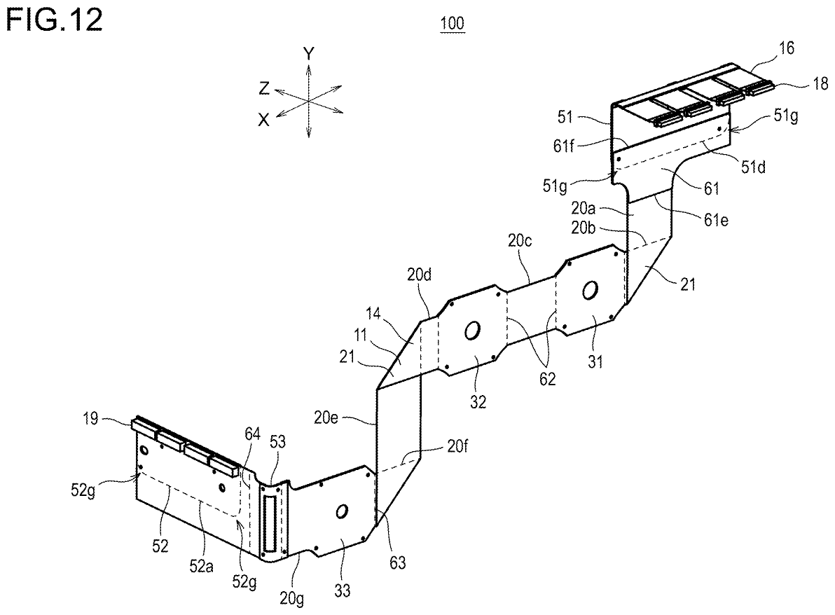

Next, a flexible printed circuit 100 according to a modification will be described with reference to FIGS. 11 and 12.

The flexible printed circuit 100 according to the present modification is different from the flexible printed circuit 100 according to the above embodiment in the following points, and is configured similarly to the flexible printed circuit 100 according to the above embodiment in the other points.

In the case of the present modification, the second metal plate 52 is smaller than the other end portion 13 of the circuit body 10 and does not protrude beyond the other end portion 13. That is, when viewed in the thickness direction of the other end portion 13, the second metal plate 52 is disposed within the outline of the other end portion 13.

In addition, in FIG. 11, the left edge of the second metal plate 52 is located on the right side of the left edge of the other end portion 13.

More specifically, in FIG. 11, the left edge of the second metal plate 52 is located on the right side of the right edge of the fourth reinforcing film 64. Therefore, in the case of the present modification, the second metal plate 52 and the fourth reinforcing film 64 do not overlap each other.

In the case of the present modification, each of the corner portions 51g at both ends of the lower (seventh narrow-width portion 20g side) edge portion 51d of the first metal plate 51 is an arc-shaped portion protruding outward from the first metal plate 51. Therefore, the breakage of the circuit body 11 starting from the region overlapping the corner portion 51g of the first metal plate 51 in the circuit body 11 is more favorably suppressed.

Similarly, the corner portions 52g at both ends of the edge portion 52a on the lower side of the second metal plate 52 are arc-shaped portions, respectively protruding outward from the second metal plate 52. Therefore, the breakage of the circuit body 11 starting from the region overlapping the corner portion 52g of the second metal plate 52 in the circuit body 11 is more favorably suppressed.

Note that the flexible printed circuit 100 may or may not have the fastening portion reinforcing member 70. In the above embodiment, the example in which the flexible printed circuit 100 includes the fastening portion reinforcing member 70 has been described, but in the present modification, the flexible printed circuit 100 does not include the fastening portion reinforcing member 70.

Although the embodiment and the modification have been described above with reference to the drawings, these are examples of the present invention, and various configurations other than the above can be adopted.

For example, in the above description, the example in which the flexible printed circuit 100 is an in-vehicle FPC cable has been described, but the flexible printed circuit 100 may be an FPC cable other than the in-vehicle FPC cable, or may be an FPC other than the FPC cable.

In addition, in the above description, the example in which the flexible printed circuit 100 is a single-sided FPC has been described, but the flexible printed circuit 100 may be a double-sided FPC.

The present embodiment includes the following technical ideas.
(1) A flexible printed circuit, including:
a flexible circuit body having a substrate, wiring formed on the substrate, and an insulating coating covering the wiring; and
a reinforcing plate laminated on the circuit body, in which
the circuit body includes a first portion and a second portion extending from the first portion with a smaller width than the first portion,
the reinforcing plate is laminated on at least the first portion among the first portion and the second portion, and
when viewed in a thickness direction of the circuit body, the reinforcing plate is disposed at a position offset toward inward side of the circuit body with respect to a boundary point between the first portion and the second portion in an outline of the circuit body.
(2) The flexible printed circuit according to (1), in which a width dimension of a boundary portion with the second portion in the first portion gradually decreases toward the second portion side.
(3) The flexible printed circuit according to (2), in which a recessed portion having a shape indented arcuately is formed in the outline of the boundary portion.
(4) The flexible printed circuit according to (3), in which a recessed portion having a shape corresponding to the recessed portion of the boundary portion is also formed in the reinforcing plate, and
when viewed in the thickness direction of the circuit body, the recessed portion of the reinforcing plate and the recessed portion of the boundary portion overlap each other.
(5) The flexible printed circuit according to any one of (1) to (4), in which an arc-shaped portion that protrudes outward from the reinforcing plate is formed at a corner portion of the reinforcing plate, and
the arc-shaped portion is disposed at a position offset toward inward side of the circuit body.
(6) The flexible printed circuit according to (5), in which the arc-shaped portion is formed at a position protruding toward the boundary point.
(7) The flexible printed circuit according to any one of (1) to (3), including a first reinforcing plate as the reinforcing plate, in which
the entire first reinforcing plate is disposed at a position offset toward inward side of the first portion from a boundary point between the first portion and the second portion when viewed in the thickness direction of the circuit body.
(8) The flexible printed circuit according to (7), in which the first reinforcing plate is a metal plate.
(9) The flexible printed circuit according to (8), including:
a resin film laminated on a surface of the circuit body opposite to a surface on which the metal plate is laminated; or interposed between the circuit body and the metal plate, in which
when viewed in the thickness direction of the circuit body, the resin film is disposed across an edge portion of the metal plate on the second portion side.
(10) The flexible printed circuit according to (1), in which:
the circuit body is formed in a band shape;
the circuit body has, as the first portion, an expanded portion formed in a middle portion of the circuit body in a longitudinal direction;
and includes a resin film laminated on the expanded portion as the reinforcing plate;
in which an arc-shaped portion protruding outward of the resin film is formed at a corner portion of the resin film; and
the arc-shaped portion is disposed at a position offset toward inward side of the circuit body.
(11) The flexible printed circuit according to (10), in which
a width dimension of a boundary portion with the second portion in the expanded portion gradually decreases toward the second portion side,
a recessed portion having a shape indented arcuately is formed in an outline of the boundary portion,
a recessed portion having a shape corresponding to the recessed portion of the boundary portion is also formed in the reinforcing plate, and
when viewed in the thickness direction of the circuit body, the recessed portion of the reinforcing plate and the recessed portion of the boundary portion overlap each other.
(12) The flexible printed circuit according to any one of (1) to (11), in which the circuit body is formed in a band shape, and
connectors connected to external devices are provided at both ends of the circuit body, respectively.

Further, the present embodiment discloses the following technical idea.
<1> A flexible printed circuit, including:
a flexible circuit body having a substrate, wiring formed on the substrate, and an insulating coating covering the wiring; and
a reinforcing plate laminated on the circuit body, in which
when viewed in a thickness direction of the circuit body, a part of an outline of the reinforcing plate is disposed at a position offset toward inward side with respect to an outline in a width direction of the circuit body.

That is, for example, in a case where a first portion and a second portion (portion extending from the first portion with a smaller width than the first portion) do not exist in the circuit body 11, the breakage of the circuit body 11 can also be suppressed when a part of the outline of the reinforcing plate is disposed at the position offset toward inward side with respect to the outline in the width direction of the circuit body 11. That is, for example, in a case where the circuit body 11 does not have the protruding portion 38 described above and the second reinforcing film 62 also does not have a region corresponding to the protruding portion 38, when the arc-shaped portion 62d is located inside the outline in the width direction of the circuit body 11, the breakage of the circuit body 11 can be also suppressed.

### Reference Signs List

11 Circuit body
12 One end portion
13 Other end portion
14 Middle portion
15 Wide-width portion
15a Constant width portion
15b Boundary portion
15c Recessed portion
16 Branch portion
17 Connecting portion
18 Connector
19 Connector
20a First narrow-width portion
20b Second narrow-width portion
20c Third narrow-width portion
20d Fourth narrow-width portion
20e Fifth narrow-width portion
20f Sixth narrow-width portion
20g Seventh narrow-width portion
21 Folded portion
22 Connecting portion
31 First expanded portion
32 Second expanded portion
33 Third expanded portion
34 Fourth expanded portion
35 Constant width portion
36 Boundary portion
37 Recessed portion
38 Protruding portion
51 First metal plate
51a Main portion
51b Sub portion
51c Bent portion
51d Edge portion
51g Corner portion
52 Second metal plate
52a Edge portion
52g Corner portion
53 Bent metal plate
61 First reinforcing film
61a Constant width portion
61b Width changing portion
61c Recessed portion
61d Arc-shaped portion
61e Edge portion
61f Edge portion
62 Second reinforcing film
62a Constant width portion
62b Width changing portion
62c Recessed portion
62d Arc-shaped portion
62e Arc-shaped portion
62f Edge portion
63 Third reinforcing film
63a Constant width portion
63b Width changing portion
63c Recessed portion
63d Arc-shaped portion
63e Extension portion
64 Fourth reinforcing film
70 Fastening portion reinforcing member
81a, 81b, 81c Pin hole
82a, 82b, 82c, 82d Fastening hole
91 Substrate
92 Wiring
93 Insulating coating
94 Adhesive layer
95 Adhesive layer
96 Adhesive layer
100 Flexible printed circuit
P1 Boundary point
C1, C2, C3 Corner portion

What is claimed is:

1. A flexible printed circuit, comprising:
a flexible circuit body having a substrate, wiring formed on the substrate, and an insulating coating covering the wiring; and
a reinforcing plate laminated on the circuit body, wherein
the circuit body includes a first portion and a second portion extending from the first portion with a smaller width than the first portion,
the reinforcing plate is laminated on at least the first portion among the first portion and the second portion, and
when viewed in a thickness direction of the circuit body, the reinforcing plate is disposed at a position offset toward inward side of the circuit body with respect to a boundary point between the first portion and the second portion in an outline of the circuit body.

2. The flexible printed circuit according to claim 1, wherein a width dimension of a boundary portion with the second portion in the first portion gradually decreases toward the second portion side.

3. The flexible printed circuit according to claim 2, wherein a recessed portion having a shape indented arcuately is formed in the outline of the boundary portion.

4. The flexible printed circuit according to claim 3, wherein a recessed portion having a shape corresponding to the recessed portion of the boundary portion is also formed in the reinforcing plate, and
when viewed in the thickness direction of the circuit body, the recessed portion of the reinforcing plate and the recessed portion of the boundary portion overlap each other.

5. The flexible printed circuit according to claim 1, wherein an arc-shaped portion that protrudes outward from the reinforcing plate is formed at a corner portion of the reinforcing plate, and
the arc-shaped portion is disposed at a position offset toward inward side of the circuit body.

6. The flexible printed circuit according to claim 5, wherein the arc-shaped portion is formed at a position protruding toward the boundary point.

7. The flexible printed circuit according to claim 1, comprising a first reinforcing plate as the reinforcing plate, wherein
the entire first reinforcing plate is disposed at a position offset toward inward side of the first portion from a boundary point between the first portion and the second portion when viewed in the thickness direction of the circuit body.

8. The flexible printed circuit according to claim 7, wherein the first reinforcing plate is a metal plate.

9. The flexible printed circuit according to claim 8, comprising: a resin film laminated on a surface of the circuit body opposite to a surface on which the metal plate is laminated; or interposed between the circuit body and the metal plate, wherein
when viewed in the thickness direction of the circuit body, the resin film is disposed across an edge portion of the metal plate on the second portion side.

10. The flexible printed circuit according to claim 1, wherein
the circuit body is formed in a band shape,
the circuit body has, as the first portion, an expanded portion formed in a middle portion of the circuit body in a longitudinal direction,
and includes a resin film laminated on the expanded portion as the reinforcing plate,
in which an arc-shaped portion protruding outward of the resin film is formed at a corner portion of the resin film, and
the arc-shaped portion is disposed at a position offset toward inward side of the circuit body.

11. The flexible printed circuit according to claim 10, wherein
a width dimension of a boundary portion with the second portion in the expanded portion gradually decreases toward the second portion side,
a recessed portion having a shape indented arcuately is formed in an outline of the boundary portion,
a recessed portion having a shape corresponding to the recessed portion of the boundary portion is also formed in the reinforcing plate, and
when viewed in the thickness direction of the circuit body, the recessed portion of the reinforcing plate and the recessed portion of the boundary portion overlap each other.

12. The flexible printed circuit according to claim 1, wherein the circuit body is formed in a band shape, and
connectors connected to external devices are provided at both ends of the circuit body, respectively.
